(19) United States
(12) Patent Application Publication
(10) Pub. No.: US 2008/0225469 A1
(43) Pub. Date: Sep. 18, 2008

(54) Easy In-Easy Out Starter

(75) Inventors: Jack Jansen van Rosendaal, Terneuzen (NL); Herman Bombeeck, Terneuzen (NL); Erik Donkers, Roosendaal (NL); Ole Christoffersen, Oslo (NO)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/064,094

(22) PCT Filed: Aug. 16, 2006
(86) PCT No.: PCT/IB06/52817

§ 371 Date: Feb. 19, 2008

(30) Foreign Application Priority Data
Aug. 23, 2005 (CN) 200520105165.1

(51) Int. Cl. H05K 7/00

(52) U.S. Cl. 361/679

(57) ABSTRACT

The present utility model relates to a starter comprising a body (12) and a pair of insert terminals (13) disposed at one end of the body (12), wherein at least one recess is formed at another end of the body (12). The starter according to the present utility model may be mounted or replaced simply and conveniently without any special tool. Furthermore, the starter according to the present utility model has a simple structure and may be manufactured simply without modifying substantially the apparatus and the process for manufacturing the conventional starter.

### FIELD OF THE INVENTION

The present invention relates to a starter.

### BACKGROUND OF THE INVENTION

The starter is used widely in many kinds of luminaries. It functions to form a closed circuit by means of discharge within a short time at the starting stage of the luminaries, thereby switching on the luminaries. After used a period of time, the starter may not function and it is necessary to replace it with a new one. FIG. 1 is a side view of a conventional starter and FIG. 2 is a top view of the starter shown in FIG. 1, showing one end that has no insert terminals. As shown in FIGS. 1 and 2, the conventional starter 1 generally comprises a cylindrical body 2 with two closed ends, an electrical assembly contained in the cylindrical body 2, a pair of insert terminals 3 extending from the electrical assembly and through one closed end, and a hole 4 at the opposite end of the cylindrical body 2 for displaying the operating status of the starter 1.

In use, the starter is inserted into the housing of the luminaries. In consideration of beauty and safety, the starter is usually recessed into the housing of the luminaries so that the starter hardly exposes to the outside at all. Since it isn't easy to access from the outside, mounting and replacing a starter becomes difficult. Therefore, some times special tools are required to mount and replace a starter. It is very inconvenient.

Accordingly, it is necessary to provide an improved starter.

### OBJECT AND SUMMARY OF THE INVENTION

An object of the invention is to overcome the defects and problems in the prior art and provide a starter, which is accessible easily from the outside without any special tools so that mounting and replacing a starter becomes simple and easy.

To achieve the object of the invention, there is provided a starter comprising a body and a pair of insert terminals disposed at one end of the body, wherein at least one recess is formed at another end of the body.

### BRIEF DESCRIPTION OF THE DRAWINGS

FIG. 1 is a side view of a conventional starter, wherein the right side is the topside of the starter and the left side is the insert terminal side of the starter.

FIG. 2 is a top view of the starter shown in FIG. 1, showing one end that has no insert terminals, i.e. the hole side of the starter.

FIG. 3 is a side view of a starter according to the present invention.

FIG. 4 is a top view of the starter shown in FIG. 3, showing one end that has no insert terminals, i.e. the side provided with the recesses.

FIG. 5 shows schematically the operation of mounting or replacing the starter according to the present invention.

FIG. 6 shows schematically the engagement state of two starters when mounting or replacing the starter according to the present invention.

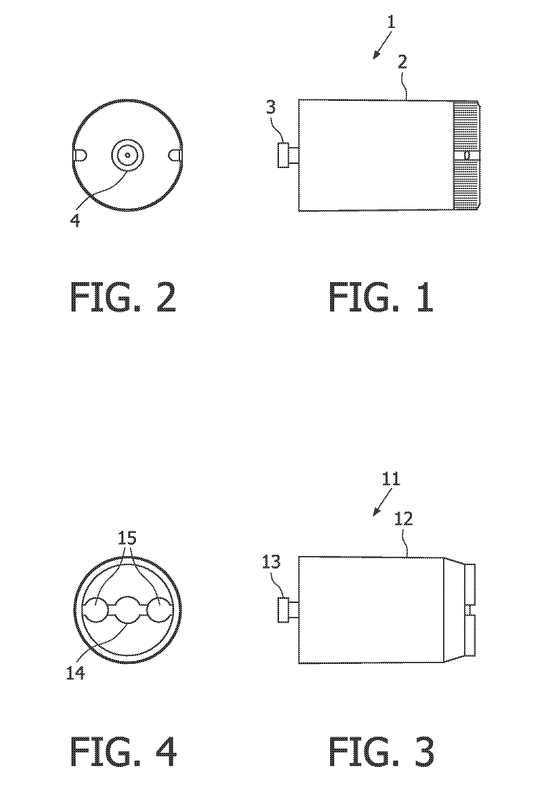

### DETAILED DESCRIPTION OF THE INVENTION

The starter according to the embodiment of the present invention will be described in detail with reference to the drawings.

FIG. 3 is a side view of a starter according to the present invention and FIG. 4 is a top view of the starter shown in FIG. 3, showing one end that has no insert terminals. As shown in FIGS. 3 and 4, the starter 11 according to the present invention generally comprises a cylindrical body 12 with two closed ends, an electrical assembly contained in the cylindrical body 12, a pair of insert terminals 13 extending from the electrical assembly and through one closed end, and a hole 14 at the opposite end of the cylindrical body 12 for displaying the operating status of the starter 11.

Unlike the conventional starter 1, the starter 11 according to the present invention further comprises a pair of recesses 15 formed at one end of the body 12 that has no insert terminals. The distance between the pair of recesses 15 may be chosen to be identical substantially to that between the pair of insert terminals 13. Preferably, the pair of recesses 15 may be disposed at positions corresponding to the pair of insert terminals 13 at the opposite end. Preferably, the shape of the pair of recesses 15 may be the same as that of the pair of insert terminals 13. Preferably, the dimension of the pair of recesses 15 may be slightly larger than that of the pair of insert terminals 13 so that the pair of insert terminals 13 insert easily into the pair of recesses 15. Of course, the starter 11 according to the present invention further may comprise a plurality of pairs of recesses 15. Preferably, each pair of recesses 15 are disposed diametrically opposite to each other.

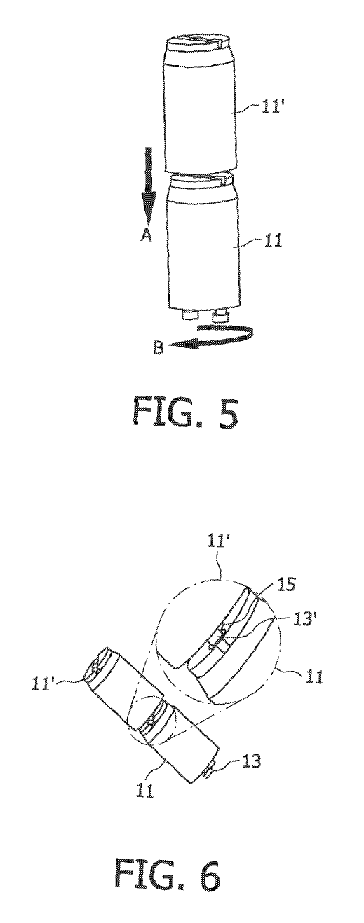

FIG. 5 shows schematically the operation of mounting or replacing the starter according to the present invention and FIG. 6 shows schematically the engagement state of two starters when mounting or replacing the starter according to the present invention. For the sake of clarification and convenience, the housing of the luminaries is not shown. As shown in FIGS. 5 and 6, in order to replace the starter 11 according to the present invention shown in the lower part, another starter 11′ inserts toward the starter 11 along the direction as shown by the arrow A so that the pair of insert terminals 13′ of the starter 11′ insert into the pair of recesses 15 formed in the end of the starter 11 that has no insert terminals. The engagement between two starters is shown in detail in FIG. 6. The starter 11′ then is rotated along a (anticlockwise) direction opposite to the direction as shown schematically by the arrow B to rotate the starter 11 along the same direction so that the starter 11 is dismounted from the housing of the luminaries. The starter 11 then is slightly pull out of the housing of the luminaries by means of the starter 11′ to be grasped by one hand. To mount a new starter, it is necessary only to insert two starters inserted together as shown in FIG. 6 into the housing of the luminaries, rotate the two starters along the (clockwise) direction as shown schematically by the arrow B and then remove the upper starter.

In another aspect, the starter according to the present invention may be mounted or replaced by means of a lamp tube of the luminaries. In such a case, the distance between the pair of recesses may be chosen to be identical substantially to that between a pair of insert terminals disposed at one end of the lamp tube. Preferably, the shape of the pair of recesses may be the same as that of the pair of insert terminals disposed at one end of the lamp tube. Preferably, the dimension of the pair of recesses may be slightly larger than that of the pair of insert terminals disposed at one end of the lamp tube so that the pair of insert terminals disposed at one end of the lamp tube insert easily into the pair of recesses. Of course, the starter according to the present invention further may comprise a plurality of pairs of recesses. Preferably, each pair of recesses are disposed diametrically opposite to each other. According to this embodiment, when it is necessary to mount or replace the starter, the pair of insert terminals disposed at one end of the lamp tube insert into the pair of recesses formed in the end of the starter that has no insert terminals and then rotate to mount or replace the starter as desired.

Obviously, the starter according to the present invention may be mounted or replaced simply and conveniently without any special tool. Furthermore, the starter according to the present invention has a simple structure and may be manufactured simply without modifying substantially the equipments and the process for manufacturing the conventional starter.

Having described the invention in detail, those skilled in the art will appreciate that modifications of this invention may be made without changing the concept of the present invention. For example, a pair of recesses formed at one end of the body that has no insert terminals may be replaced with one S-shaped, elliptical or rectangular recess. With the insert terminals of another starter inserted into the S-shaped, elliptical or rectangular recess, it is possible to mount or replace conveniently the starter without using a special tool. Therefore, it is not intended to limit the present invention only to the preferred embodiments illustrated and described. Rather, the scope of the invention is to be determined by the appended claims and their equivalents.

1. A starter comprising a body (12) and a pair of insert terminals (13) disposed at one end of the body (12), wherein at least one recess is formed at another end of the body (12).

2. A starter as claimed in claim 1, wherein said starter comprises at least one pair of recesses (15) formed at another end of the body (12).

3. A starter as claimed in claim 2, wherein the distance between each pair of said at least one pair of recesses (15) is chosen to be identical substantially to that between said pair of insert terminals (13).

4. A starter as claimed in claim 2, wherein the shape of said at least one pair of recesses (15) is the same as that of the pair of insert terminals (13).

5. A starter as claimed in claim 2, wherein the dimension of said at least one pair of recesses (15) is slightly larger than that of the pair of insert terminals (13).

6. A starter as claimed in claim 2, wherein said starter comprises a pair of recesses (15) and the pair of recesses (15) are disposed at positions corresponding to the pair of insert terminals (13) at the opposite end.

7. A starter as claimed in claim 2, wherein the distance between each pair of said at least one pair of recesses (15) is chosen to be identical substantially to that between a pair of insert terminals disposed at one end of the lamp tube of a luminaries.

8. A starter as claimed in claim 2, wherein the shape of said at least one pair of recesses (15) is the same as that of a pair of insert terminals disposed at one end of the lamp tube of a luminaries.

9. A starter as claimed in claim 2, wherein the dimension of said at least one pair of recesses (15) is slightly larger than that of a pair of insert terminals disposed at one end of the lamp tube of a luminaries.

10. A starter as claimed in claim 2, wherein comprising a plurality of pairs of recesses (15), each pair being disposed diametrically opposite to each other.

11. A starter as claimed in claim 2, wherein said body (12) is a cylindrical body with two closed ends.

12. A starter as claimed in claim 2, wherein further comprising an electrical assembly contained in the body (12), the pair of insert terminals (13) extend from the electrical assembly and through one end of the body (12).

13. A starter as claimed in claim 2, wherein a hole (14) for displaying the operating status of the starter is formed at the another end of the body (12).
